(19) United States
(12) Patent Application Publication
(10) Pub. No.: US 2007/0059913 A1
(43) Pub. Date: Mar. 15, 2007

(54) Capping layer to reduce amine poisoning of photoresist layers

(76) Inventors: Sean W. King, Hillsboro, OR (US); George A. Antonelli, Portland, OR (US); Tony V. Mule, Hillsboro, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/229,131

(22) Filed: Sep. 15, 2005

(51) Int. Cl. H01L 21/44

(52) U.S. Cl. 438/597

(57) ABSTRACT

An apparatus for reducing amine poisoning of photoresist layers comprises a substrate, an etch stop layer containing amines formed over the substrate, and a dense capping layer formed directly on the etch stop layer, wherein the dense capping layer substantially prevents the amines from diffusing out of the etch stop layer and into a subsequently formed photoresist layer. The dense capping layer may comprise silicon carbide, silicon carboxide, or a combination of silicon carbide and silicon carboxide. The dense capping layer may have a density greater than or equal to 2 g/cm³ and a thickness that ranges from 10 Å to 200 Å.

### BACKGROUND

In the manufacture of integrated circuits, processing steps that generate nitride layers, such as metal nitride or silicon nitride layers, tend to introduce amines or imines into the integrated circuit structure. For instance, the formation of metal nitride or silicon nitride etch stop layers or barrier layers tends to introduce amines into subsequently formed layers of the integrated circuit, such as interlayer dielectrics (ILDs). The influx of amines or imines into an ILD is particularly problematic when the ILD is a low density or porous dielectric. This is problematic because the later out-gassing of amines or imines may poison subsequently formed photoresist layers, compromising their use in photolithography processes. Amine-poisoning has been correlated with downstream defects in lithography such as blocked etch extra patterns, which ultimately produces defective integrated circuits and reduces the yield of a semiconductor wafer.

One conventional method for addressing this issue is using dense silicon dioxide films as the ILD. Amines and imines from the underlying nitride layers cannot readily diffuse through the dense silicon dioxide film. This prevents the amines or imines from reaching the photoresist layers during a subsequent photolithography process. Unfortunately, dense silicon dioxide layers cannot be used in modern integrated circuits, such as circuits built using 90 nm or 65 nm technology. This is because as semiconductor device dimensions decrease, electrical components such as interconnects must be formed closer together. This increases the capacitance between components with the resulting interference and crosstalk degrading device performance. To address this issue, dielectric materials with lower dielectric constants (i.e., low-k dielectric materials) are used to provide better insulation between electrical components. These low-k dielectrics have low densities and are often porous.

Another approach for addressing photoresist poisoning issues employs a dense hard mask that is used on top of a low-k dielectric layer to achieve tighter critical dimension control. The dense hard mask naturally prevents amines or imines from escaping out of the low-k dielectric layer and into a photoresist layer. Unfortunately, the amine/imine concentration tends to build up within the low-k dielectric layer, and when the ILD is subsequently patterned to form trenches and vias, the amines or imines escape and poison any subsequently formed photoresist layers. As such, improved techniques are needed to address the photoresist poisoning problem presented by nitride layers used in integrated circuit processing.

### BRIEF DESCRIPTION OF THE DRAWINGS

FIG. 1 illustrates layers of an integrated circuit structure formed in accordance with an implementation of the invention.

FIG. 2 is a method for forming an integrated circuit structure that includes a dense capping layer in accordance with an implementation of the invention.

### DETAILED DESCRIPTION

Described herein are systems and methods related to the use of a dense capping layer to prevent amine poisoning of photoresist layers. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

Implementations of the invention include a dense capping layer that is formed directly atop a nitride layer within an integrated circuit. The dense capping layer forms a barrier to substantially prevent amines or imines from diffusing out of the nitride layer and entering any subsequently formed layers, such as subsequently formed dielectric layers or photoresist layers. The nitride layer that is capped by the dense capping layer may be, for instance, a nitride etch stop layer or an amine containing dielectric film. In various implementations of the invention, the dense capping layer may be formed from undoped silicon carbide or oxygen-doped silicon carbide. By preventing the amines or imines from diffusing into the later formed dielectric layers, the amines or imines are ultimately prevented from poisoning any subsequently formed photoresist layers. As such, the number of photolithography related defects decreases and the yield of a semiconductor increases.

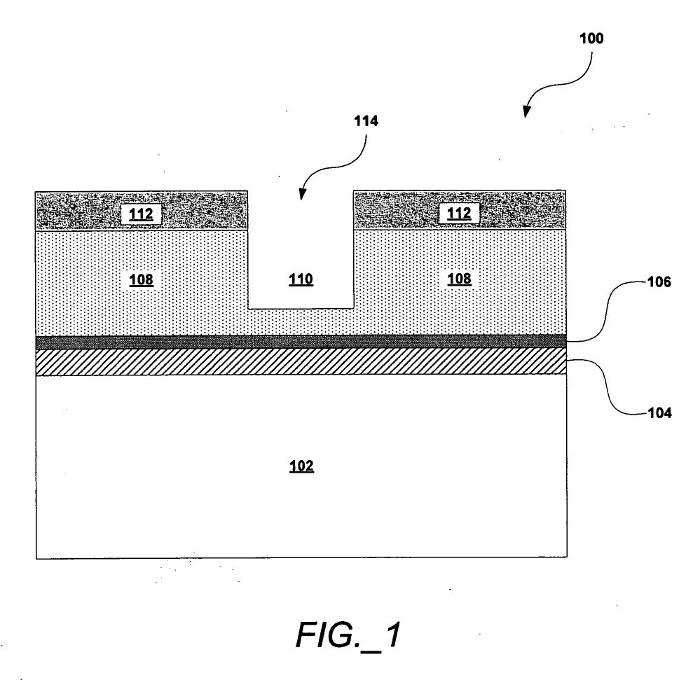

FIG. 1 illustrates a portion of an integrated circuit structure 100 formed in accordance with an implementation of the invention. The integrated circuit structure 100 shown is a transitional structure created during a metal interconnect formation process. The integrated circuit structure 100 may be formed upon a substrate 102. The substrate 102 may consist of a semiconductor material such as silicon or strained silicon. In implementations of the invention, the substrate 102 may be provided by a semiconductor wafer, such as a silicon wafer or a silicon-on-insulator (SOI) wafer. Devices such as transistors (not shown) may be built on the substrate 102.

An etch stop layer 104 may be deposited atop the substrate 102. The etch stop layer 104 may be formed using a nitrogen or nitride containing material such as a metal nitride or silicon nitride. In one implementation, the etch stop layer 104 may be a silicon carbonitride (SiCN) film. In other implementations, the etch stop layer 104 may be an alternative amine-doped dielectric film. The etch stop layer 104, therefore, contains amines or imines that are capable of diffusing out of the etch stop layer 104 and into adjacent layers, such as subsequently formed dielectric layers.

An ILD layer 108 may be formed over the etch stop layer 104. The ILD layer 108 may be formed using a variety of dielectric materials known in the art for use within an integrated circuit. Examples of dielectric materials that may be used to form the ILD layer 108 include, but are not limited to, oxides such as silicon dioxide (SiO₂) and carbon doped oxide (CDO), organic polymers such as perfluorocyclobutane (PFCB), or fluorosilicate glass (FSG).

The devices, such as transistors, on the substrate 102 may be coupled together using metal interconnects. The transitional structure 100 shown in FIG. 1 illustrates an etched trench 110 that will house at least one of those metal interconnects. Although not shown, the metal interconnect itself will generally be made from copper metal and are formed using a dual damascene process wherein copper metal is deposited into the etched trench 110.

Conventional photolithography processes may be used to etch the ILD layer 108 to form the trench 110. FIG. 1 illustrates how a photoresist layer 112 may be deposited atop the ILD layer 108. As is well known in the art, the photoresist layer 112 may be patterned and developed to form an opening 114 that corresponds to the trench 110 that is to be etched into the ILD layer 108. An etching process follows wherein an etchant contacts portions of the ILD layer 108 exposed by the opening 114 and removes dielectric material to form the trench 110. After the trench 110 is formed, the photoresist layer 112 will generally be removed prior to metal deposition within the trench 110.

In accordance with implementations of the invention, a dense capping layer 106 may be formed atop the etch stop layer 104. The dense capping layer 106 is a dense, non-amine and non-nitrogen containing layer that functions to prevent amines or imines from diffusing out of the etch stop layer 104 and into the ILD layer 108 that is deposited atop the etch stop layer 104. Since the amines or imines are barred from diffusing into the over-lying ILD layer 108, the amines or imines cannot poison the photoresist layer 112 that is deposited atop the ILD layer 108 during a subsequent photolithography process. In other words, the amines and or imines are substantially prevented from diffusing through the ILD layer 108 and into the deposited photoresist layer 110. The dense capping layer 106 of the invention therefore substantially reduces photoresist poisoning that often occurs in the prior art. Subsequent photolithography processes, such as the process used to etch the trench 110, are therefore less adversely affected by the use of a nitride containing etch stop layer 104.

In implementations of the invention, the dense capping layer 106 may consist of a dense dielectric material. In some implementations, the dense capping layer 106 may comprise a thin layer of silicon carbide (SiC), a thin layer of oxygen-doped silicon carbide, also known as silicon carboxide (SiCO), or a thin layer of a combination of SiC and SiCO. When a combination of SiC and SiCO forms the dense capping layer 106, any ratio of SiC to SiCO may be used. In alternate implementations, the dense capping layer 106 may comprise a thin layer of a dense silicon dioxide material.

The density and thickness of the dense capping layer 106 may be set such that amines or imines are unable to diffuse through the layer and reach the photoresist layer 110. In some implementations, the dense capping layer 106 may have a density that is at or above a critical density of approximately 2 grams per cubic centimeter (g/cm³). In implementations of the invention, the dense capping layer 106 may have a thickness that ranges from around 10 Angstroms (Å) to around 200 Å. In some implementations the critical thickness of the dense capping layer 106 may be around 100 Å.

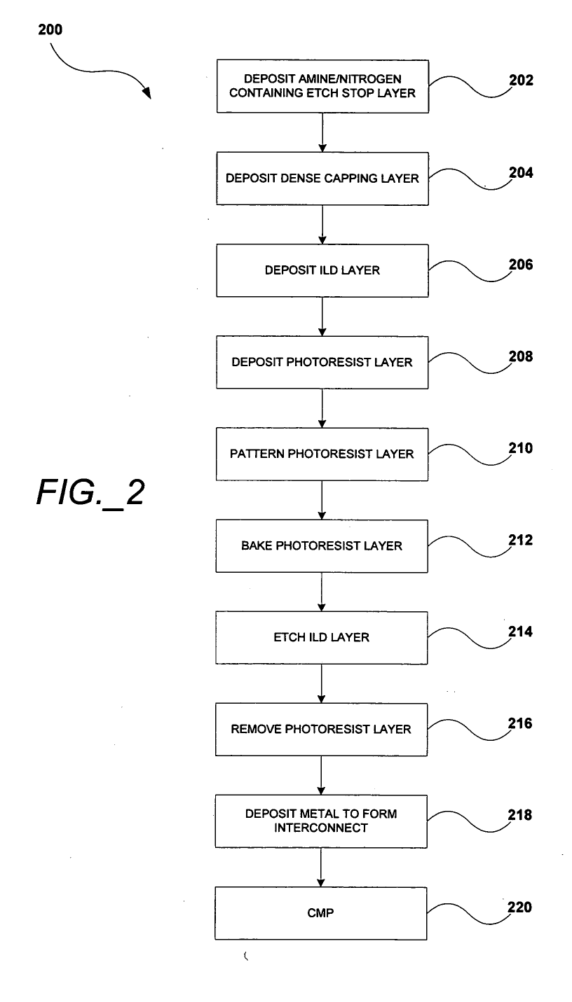

FIG. 2 is a method 200 of forming a dense capping layer in accordance with an implementation of the invention. The method 200 begins with the deposition of an etch stop layer on a substrate (202). The etch stop layer may be an amine or nitrogen containing dielectric material, such as a silicon carbonitride (SiCN) film. The etch stop layer may be deposited using any conventional process known in the art, such as a plasma enhanced chemical vapor deposition (PECVD) process. Other processes that may be used to deposit the etch stop layer atop the substrate include, but are not limited to, chemical vapor deposition (CVD), physical vapor deposition (PVD), atomic layer deposition (ALD), spin-on dielectric processes (SOD), and epitaxial growth.

A dense capping layer is then deposited atop the etch stop layer (204). As described above, the dense capping layer prevents amines and imines in the etch stop layer from diffusing out of the etch stop layer and into ILD layers and photoresist layers that will be formed over the etch stop layer. The dense capping layer may consist of one or both of SiC and SiCO. In implementations of the invention, the dense capping layer may be deposited atop the etch stop layer using processes such as PECVD or high density plasma (HDP) vapor deposition (e.g., HDP-PECVD). Alternate deposition processes that may be used include CVD, PVD, and ALD.

In accordance with the invention, the process to deposit the dense capping layer may use deposition precursors that do not contain nitrogen, thereby forming a dense capping layer that does not contain amines. The density and thickness of the dense capping layer may be controlled and established during the deposition process to ensure that the amines and imines from the underlying etch stop layer can not diffuse through the dense capping layer. Furthermore, in implementations of the invention, the step coverage and sidewall density of the dense capping layer may also be controlled during the deposition process to ensure that the thickness and density of the dense capping layer film over all topography is above the critical thickness and critical density needed to prevent amines and imines from the diffusing through the dense capping layer.

An ILD layer is then deposited atop the dense capping layer (206). This is at least one of the ILD layers that is being protected from diffusing amines or imines by the dense capping layer. The ILD layer may consist of a low-k dielectric material, including but not limited to silicon dioxide or carbon doped oxide. The ILD layer may be deposited using well known deposition techniques for dielectric layers that include, but are not limited to, CVD, PECVD, PVD, ALD, SOD, and epitaxial growth.

After the ILD layer is deposited, a photolithography process may be carried out to etch vias and trenches into the ILD. The photolithography process may include depositing a photoresist layer atop the ILD layer (208). In some implementations, the deposited photoresist layer may be subjected to a soft baking process. Next, the photoresist layer may be patterned by first exposing the photoresist layer to radiation (e.g., ultraviolet radiation) through a patterned mask and then developing the photoresist layer (210). Developing the photoresist layer removes portions of the photoresist material and leaves behind a pattern that corresponds to the mask pattern. The patterned photoresist layer may then be baked to harden the photoresist material (212). In accordance with the invention, the use of the dense capping layer substantially prevents the photoresist layer from being poisoned by amines or imines, therefore, the number of defects in the patterned photoresist layer is greatly reduced.

The ILD layer is then etched to form the vias and trenches (214). Etching processes to form the vias and trenches using a photoresist layer are well known in the art. The photoresist layer may then be removed after the trenches and vias are formed (216). Next, the layers needed to form the metal interconnects may be deposited into the etched vias and trenches (218). These layers include, but are not limited to, barrier layers, metal seed layers, and metal layers. Processes such as electroless plating and/or electroplating may be used to deposit these layers.

Finally, a chemical mechanical polishing process (CMP) may be used to planarize the deposited metal and remove any unnecessary portions (220). The CMP process completes the formation of the metal interconnect.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

1. An apparatus comprising:
a substrate;
an etch stop layer containing amines formed over the substrate; and
a dense capping layer formed directly on the etch stop layer, wherein the dense capping layer substantially prevents the amines from diffusing out of the etch stop layer and into a subsequently formed layer.

2. The apparatus of claim 1, further comprising:
a dielectric layer formed atop the dense capping layer; and
a photoresist layer formed atop the dielectric layer, wherein the dense capping layer substantially prevents the amines from diffusing out of the etch stop layer and into the photoresist layer.

3. The apparatus of claim 1, wherein the substrate comprises a silicon wafer.

4. The apparatus of claim 1, wherein the etch stop layer comprises a silicon carbonitride film.

5. The apparatus of claim 1, wherein the dense capping layer comprises at least one of silicon carbide and silicon carboxide.

6. The apparatus of claim 1, wherein the dense capping layer has a density that is at least 2 g/cm³.

7. The apparatus of claim 1, wherein the dense capping layer has a thickness that is greater than or equal to 10 Å and less than or equal to 200 Å.

8. The apparatus of claim 2, wherein the dielectric layer comprises silicon dioxide or carbon doped oxide.

9. The apparatus of claim 1, wherein the amines comprise amines or imines.

10. The apparatus of claim 1, further comprising:
a dielectric layer formed atop the dense capping layer; and
a metal interconnect formed on the dielectric layer.

11. A dense capping layer comprising silicon carbide and having a density greater than or equal to 2 g/cm³ and a thickness that ranges from 10 Å to 200 Å, wherein the dense capping layer functions to prevent the diffusion of amines or imines.

12. The dense capping layer of claim 11, further comprising silicon carboxide.

13. The dense capping layer of claim 11, wherein the dense capping layer is formed directly on a dielectric material that includes nitrogen.

14. The dense capping layer of claim 11, wherein the dense capping layer is formed directly on a dielectric material that includes an amine.

15. A dense capping layer comprising silicon carboxide and having a density greater than or equal to 2 g/cm³ and a thickness that ranges from 10 Å to 200 Å, wherein the dense capping layer functions to prevent the diffusion of amines or imines.

16. The dense capping layer of claim 15, further comprising silicon carbide.

17. The dense capping layer of claim 15, wherein the dense capping layer is formed directly on a dielectric material that includes nitrogen.

18. The dense capping layer of claim 15, wherein the dense capping layer is formed directly on a dielectric material that includes an amine.

19. A method comprising:
providing a substrate;
depositing an etch stop layer on the substrate, wherein the etch stop layer includes amines; and
depositing a dense capping layer on the etch stop layer, wherein the dense capping layer functions to prevent the amines from diffusing out of the etch stop layer and into a subsequently deposited layer.

20. The method of claim 19, wherein the substrate comprises a silicon wafer.

21. The method of claim 19, wherein the etch stop layer comprises a silicon carbonitride layer.

22. The method of claim 21, wherein the depositing of the etch stop layer comprises using PECVD, CVD, PVD, or ALD to deposit the silicon carbonitride layer.

23. The method of claim 19, wherein the dense capping layer comprises a silicon carbide layer.

24. The method of claim 23, wherein the depositing of the dense capping layer comprises using PECVD, CVD, PVD, or ALD to deposit the silicon carbide layer.

25. The method of claim 23, wherein the dense capping layer further includes silicon carboxide.

26. The method of claim 19, further comprising:
depositing a dielectric layer on the dense capping layer; and
depositing a photoresist layer on the dielectric layer.

27. The method of claim 26, wherein the dielectric layer comprises silicon dioxide or carbon doped oxide.

28. The method of claim 26, wherein the dense capping layer substantially prevents amines from the etch stop layer from diffusing into the photoresist layer.
